(19) United States
(12) Patent Application Publication
(10) Pub. No.: US 2026/0299035 A1
(43) Pub. Date: Oct. 1, 2026

(54) CELL STATE-OF-CHARGE ESTIMATION FOR ENERGY STORAGE SYSTEMS UTILIZING MAINTENANCE MODE

(71) Applicant: Nuvation Research Corporation, Sunnyvale, CA (US)

(72) Inventors: Manoj Mathew, Kitchener (CA); Steven Miller, Sunnyvale, CA (US); Alex Green, Sunnyvale, CA (US)

(73) Assignee: Nuvation Research Corporation, Sunnyvale, CA (US)

(21) Appl. No.: 19/578,620

(22) Filed: Mar. 25, 2026

Related U.S. Application Data
(60) Provisional application No. 63/777,114, filed on Mar. 25, 2025.

(51) Int. Cl. G01R 31/3842; G01R 31/396; H02J 7/82; H02J 7/90

(52) U.S. Cl. CPC G01R 31/3842; G01R 31/396; H02J 7/82; H02J 7/933; H02J 2207/20

(57) ABSTRACT

A state-of-charge estimation system disclosed herein may comprise: an energy storage system comprising one or more stacks; a measurement module comprising a voltage measurement device and a current measurement device; a stack state-of-charge estimation module configured to estimate a stack state-of-charge based on one or more cell voltage measurements and stack current measurement; a static gradient generation module for estimating a gradient of an open circuit voltage curve based on the one or more cell voltage measurements; a maintenance control module configured to determine an estimation signal based on the stack state-of-charge and the gradient for each of the one or more stacks; wherein the maintenance control module is configured to send instructions to a power conversion system to bring the one or more stacks to a specified state-of-charge based on the stack state-of-charge; and a cell state-of-charge estimation module configured to estimate a cell state-of-charge estimate.

### CROSS-REFERENCE TO RELATED APPLICATION

This application claims priority to U.S. Provisional Patent Application No. 63/777,114, filed Mar. 25, 2025, and entitled “CELL STATE-OF-CHARGE ESTIMATION FOR ENERGY STORAGE SYSTEMS UTILIZING MAINTENANCE MODE,” the disclosures of which are hereby incorporated by reference herein.

### FIELD OF INVENTION

The present disclosure relates generally to estimation of cell level state-of-charge (“SOC”) for multi-stack energy storage systems.

### BACKGROUND

Safe management and control of an energy storage system (“ESS”) requires accurate estimation of battery state-of-charge (“SOC”). The SOC is used to represent the amount of charge remaining within a single battery cell, stack of cells or battery pack and is often expressed as a percentage of the total capacity. For example, 0% may be completely discharged and 100% may be fully charged and 50% means it has half of its total capacity remaining.

Various SOC estimation techniques have been used, including traditional coulomb counting and model-based approaches. Traditional coulomb counting involves measuring the current flowing into and out of the battery and accumulating the current over time. Due to the continuous accumulation of current over time, any errors in the current measurements will also continue to grow over time. This results in unbounded SOC error that can be problematic for the ESS. A model-based approach for SOC estimation is where voltage measurements are combined with a battery model to estimate cell SOC and correct for current measurement error. The limitation with the model-based approach is that for battery chemistries like Lithium Iron Phosphate (“LFP”), where the Open Circuit Voltage (“OCV”) curve is very flat, the estimation error can be significant.

Therefore, systems, methods and devices that provide an accurate estimate of cell SOC is desirable, particularly for battery chemistries that produce very flat OCV curves, such as for example lithium-ion chemistries and/or LFP.

### SUMMARY

A state-of-charge estimation system is disclosed herein. In various embodiments, the state-of-charge estimation system may comprise an energy storage system comprising one or more stacks, wherein each of the one or more stacks contain one or more cells. In various embodiments, the state-of-charge estimation system may further comprise a measurement module comprising a voltage measurement device and a current measurement device; wherein the voltage measurement device is configured to measure a cell voltage measurement of one or more of the cells of one or more of the stacks; wherein the current measurement device is configured to measure a stack current measurement of one or more of the stacks. In various embodiments, the state-of-charge estimation system may further comprise a stack state-of-charge estimation module for receiving the cell voltage measurements and the stack current measurement and configured to estimate a stack state-of-charge based on the one or more cell voltage measurements and the stack current measurement. In various embodiments, the state-of-charge estimation system may further comprise a static gradient generation module for estimating a gradient of an open circuit voltage curve based on the one or more cell voltage measurements. In various embodiments, the state-of-charge estimation system may further comprise a maintenance control module configured to receive the stack state-of-charge and the gradient for each of the one or more stacks, and determine an estimation signal; wherein the maintenance control module is configured to send instructions to a power conversion system to bring the one or more stacks to a specified state-of-charge based on the stack state-of-charge. In various embodiments, the state-of-charge estimation system may further comprise a cell state-of-charge estimation module configured to estimate a cell state-of-charge estimate based on the cell voltage measurements of one or more of the cells of one or more of the stacks and in response to the estimation signal.

A cell state-of-charge estimation method is disclosed herein. The cell state-of-charge estimation method may comprise measuring, by a measurement module comprising a voltage measurement device and a current measurement device, a cell voltage measurement of one or more cells of one or more stacks of an energy storage system, and a stack current measurement. The cell state-of-charge estimation method may further comprise estimating, by a stack state-of-charge estimation module, a stack state-of-charge based on the one or more cell voltage measurements and the stack current measurement. The cell state-of-charge estimation method may further comprise determining, by a static gradient generation module, a gradient of an open circuit voltage curve based on the one or more cell voltage measurements. The cell state-of-charge estimation method may further comprise determining, by the maintenance control module, an estimation signal based on the stack state-of-charge and the gradient for each of the one or more stacks; wherein the maintenance control module is configured to send instructions to a power conversion system to bring the one or more stacks to a specified state-of-charge based on the stack state-of-charge. The cell state-of-charge estimation method may further comprise estimating, by a cell state-of-charge estimation module, a cell state-of-charge estimate based on the cell voltage measurements of one or more of the cells of one or more of the stacks and in response to the estimation signal.

A state-of-charge estimation device is disclosed herein. The state-of-charge estimation device may comprise an energy storage system comprising one or more stacks, wherein each of the one or more stacks contain one or more cells. The state-of-charge estimation device may further comprise a measurement module comprising a voltage measurement device and a current measurement device; wherein the voltage measurement device is configured to measure a cell voltage measurement of one or more of the cells of one or more of the stacks; wherein the current measurement device is configured to measure a stack current measurement of one or more of the stacks. The state-of-charge estimation device may further comprise a stack computing unit for each of the one or more stacks, the stack computing unit for receiving the cell voltage measurement and the stack current measurement and determine a stack state-of-charge. The state-of-charge estimation device may further comprise an energy management controller for determining a power request based on the stack state-of-charge. The state-of-charge estimation device may further comprise a power conversion system for controlling the energy storage system based on the power requests.

### BRIEF DESCRIPTION OF THE DRAWING FIGURES

Additional aspects of the present disclosure will become evident upon reviewing the non-limiting embodiments described in the specification and the claims taken in conjunction with the accompanying figures, wherein like numerals designate like elements, and:

FIG. 1A is a diagram illustrating an example energy storage cell;

FIG. 1B is a diagram illustrating an example stack;

FIG. 2 is a block diagram illustrating a multi-stack system topology, with C connected stacks and D disconnected stacks, in accordance with various embodiments;

FIG. 3 is a diagram illustrating a state-of-charge estimation system, in accordance with various embodiments;

FIG. 4 is an exemplary OCV curve diagram, in accordance with various embodiments;

FIG. 5 is a block diagram illustrating a state-of-charge estimation system, in accordance with various embodiments;

FIG. 6 is a block diagram of the operation modes of the energy storage system;

FIG. 7 is an example gradient of the OCV curve, in accordance with various embodiments; and

FIG. 8 illustrates a method of cell state-of-charge estimation, in accordance with various embodiments.

### DETAILED DESCRIPTION

The following detailed description of various embodiments herein refers to the accompanying drawings, which show various embodiments by way of illustration. While these various embodiments are described in sufficient detail to enable those skilled in the art to practice the disclosure, it should be understood that other embodiments may be realized and that changes may be made without departing from the scope of the disclosure. Thus, the detailed description herein is presented for purposes of illustration only and not of limitation. Furthermore, any reference to singular includes plural embodiments, and any reference to more than one component or step may include a singular embodiment or step. Also, any reference to attached, fixed, connected, or the like may include permanent, removable, temporary, partial, full or any other possible attachment option. Additionally, any reference to without contact (or similar phrases) may also include reduced contact or minimal contact. It should also be understood that unless specifically stated otherwise, references to “a,” “an” or “the” may include one or more than one and that reference to an item in the singular may also include the item in the plural. Further, all ranges may include upper and lower values and all ranges and ratio limits disclosed herein may be combined.

Reference will now be made to the exemplary embodiments illustrated in the drawings, and specific language will be used herein to describe the same. It will nevertheless be understood that no limitation of the scope of the disclosure is thereby intended. Alterations and further modifications of the inventive features illustrated herein, and additional applications of the principles of the disclosure as illustrated herein, which would occur to one skilled in the relevant art and having possession of this disclosure, are to be considered within the scope of the disclosure.

Disclosed herein are systems, devices and methods for estimating a cell state-of-charge estimate. The systems, devices and methods for estimating cell state-of-charge may estimate SOC of one or more individual cells of one or more stacks in an energy storage system (“ESS”). In various embodiments, the state-of-charge estimation system may comprise a controller configured to apply a specific power profile to the ESS and bring the ESS to a state where an accurate estimate is possible. In various example embodiments, an accurate estimate of cell SOC is used to implement important BMS functions, including cell balancing, stack SOC, cell and stack capacity and cell and stack state-of-health (“SOH”).

In accordance with various example embodiments, an ESS is a system that stores and releases electrical charge. The ESS may comprise electrochemical cells, such as lead-acid batteries, nickel-cadmium batteries, nickel-metal hydride batteries, lithium-ion batteries, lithium-ion polymer batteries, LFP, zinc-air batteries, sodium-ion batteries, and/or the like. Moreover, the ESS may comprise any suitable rechargeable ESS for which cell level state-of-charge is relevant.

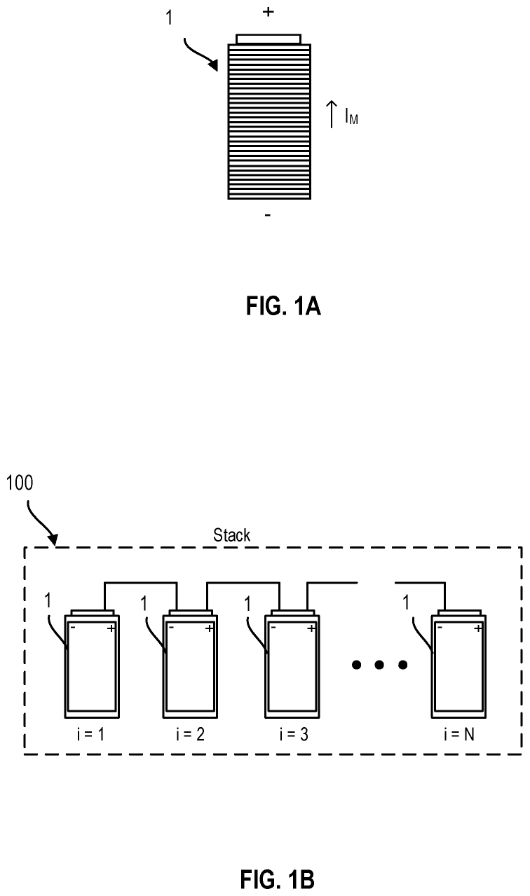

In the various example embodiments described herein, and with reference to FIGS. 1A and 1, an ESS may comprise, in an example embodiment, a battery cell 1, or simply “cell” for short. In an example embodiment, the cell 1 comprises a single anode and cathode separated by electrolyte and is used to store and release electrical charge. Multiple anodes and cathodes may be joined together in parallel or series arrangements to produce cells that operate at higher voltage or current levels. The cell may be the smallest measurable unit of energy storage within an ESS. The current flowing through the cell 1 is denoted Iₘ, where a positive current flows out of the positive terminal. A typical cell can be physically arranged as a cylindrical cell, such as the 18650 and 21700 cylindrical lithium-ion format cells, button cells, prismatic cells, pouch cells, and/or the like. Moreover, a cell may comprise any chemistry and format suitable for rechargeable energy storage where multi-stack management is relevant. Generally, the cell 1 may be any rechargeable energy storage device with connection points for a single voltage measurement.

Moreover, an ESS may comprise, in an example embodiment a battery module, or simply “module” for short. A module may comprise two or more cells connected in series or parallel arrangements or both series and parallel arrangements and grouped together. A module may be the smallest measurable unit in the ESS, if the individual cells are integrated into the module in such a way that measurement of voltage from the individual cells is not convenient.

Moreover, an ESS may comprise, in an example embodiment, a battery stack 100, stack of cells, or simply “stack” for short. The stack 100, in an example embodiment, comprises multiple cells or modules electrically connected in series. Thus, in an example embodiment, a stack 100 may comprise N cells, and each cell, in the stack of cells, may be noted as cell n wherein n=1 to N. It will be understood that N may be any positive integer number. For N>1, the stack comprises a number of cells, N. A group of series connected cells may be called a stack, or stack of cells or string.

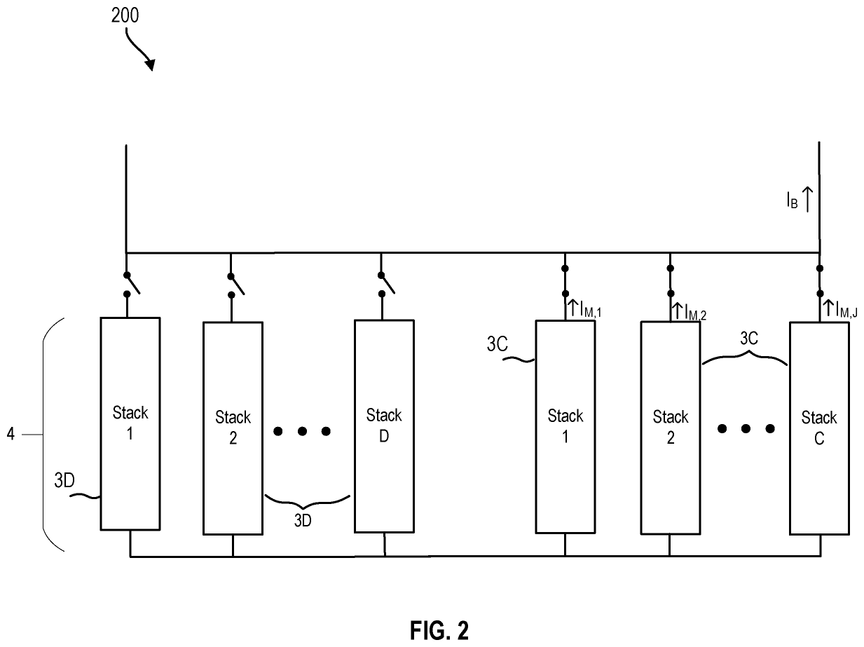

Moreover, an ESS may comprise, in an example embodiment, and with reference to FIG. 2, a multi-stack system 200 comprising a battery pack 4. In various embodiments, a battery pack 4, may be referred to as simply “pack” for short. In various embodiments, the pack 4 may be referred to as a battery bank or “bank.” The pack 4, in an example embodiment, comprises multiple stacks (e.g. stacks 3C and stacks 3D), electrically connected in parallel. Thus, in an example embodiment, a pack 4 may comprise J connected stacks at any particular time. In various embodiments, and as shown in FIG. 2, the pack 4 may comprise additional disconnected stacks 3D, which may be added at some point in time in parallel with stacks 3C. The current flowing through the pack 4 is denoted I_{B}, which is also electrically equivalent to the sum of the individual stack currents I_{M,1 . . . J}. The number of stacks in pack 4 that are connected to a shared DC-bus, may change over time dynamically where one or more stack(s) can be connected or disconnected from the pack 4 using contactors, circuit breakers, solid-state switches, or any other suitable means of making or breaking current flow.

In an example embodiment, the pack 4 can comprise C connected stacks (c=1 . . . C), where the stacks are electrically connected to a shared DC bus. The pack 4 can further comprise D disconnected stacks (d=1 . . . D), where the stack is disconnected from the shared DC bus. Thus, in an example embodiment, the sum of the total connected stacks C and the total disconnected stacks D equals the total number of stacks in the ESS, denoted J.

In an example embodiment, the D disconnected stacks (d=1 . . . D), may first be connected to a pre-charge circuit (not shown), prior to connection to the shared DC bus. For example, in various embodiments, the multi-stack system 200 may connect one or more disconnected stacks to a pre-charge circuit to prevent large in-rush currents from the power conversion system (PCS) capacitor, then once the stack has reached a suitable low current flow, the disconnected stack D may be connected to the shared DC bus.

In various embodiments, the multi-stack system 200 may be connected to a grid, generator or other items (not shown). In various embodiments, the multi-stack system 200 may be connected to an inverter, power conversion system (PCS) or other device.

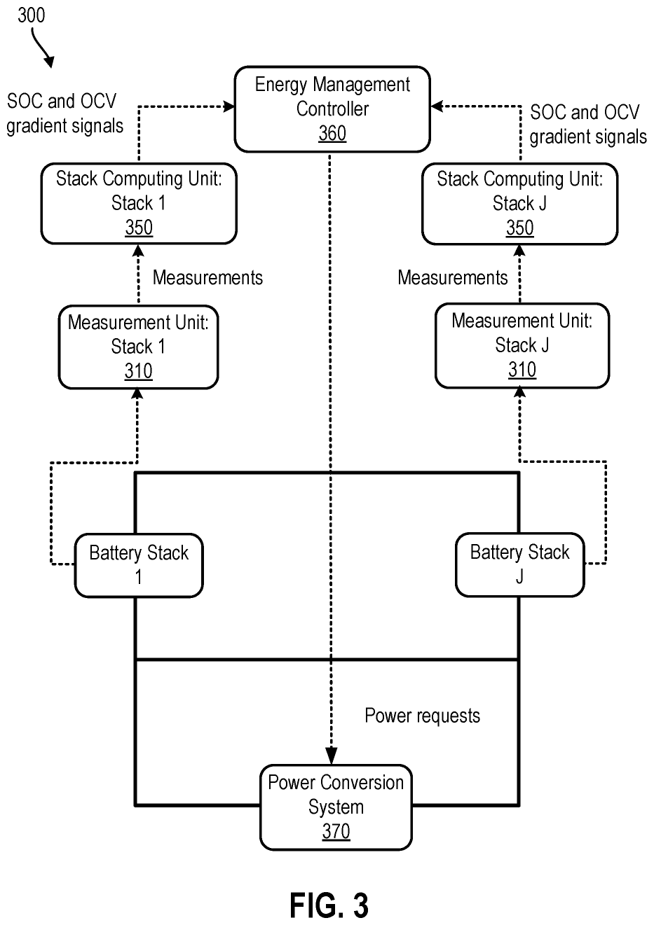

With reference now to FIG. 3, a state-of-charge estimation system 300 is shown in accordance with various embodiments. In various embodiments, the state-of-charge estimation system 300 may comprise a measurement unit 310 connected to each of the battery stacks, configured to measure the cell voltage measurement and/or stack current measurement of the ESS. The SOC estimation system 300 may further comprise a stack computing unit 350, for each of the battery stacks J, configured for receiving the cell voltage measurement and stack current measurement and determining a stack state-of-charge and an OCV curve gradient. The SOC estimation system 300 may further comprise an energy management controller 360 configured to receive the stack state-of-charge and OCV curve gradient for each stack and send power requests to the power conversion system 370. In various embodiments, the energy management controller 360 may be in communication, either directly or indirectly, with J stacks of an ESS.

In various embodiments, each of the J stacks may each be connected to a measurement unit 310. In various embodiments, a measurement unit 310 may be connected to one or more stacks. The measurement unit 310 may comprise a current measurement circuit and/or a voltage measurement circuit. In various embodiments, the measurement unit 310 may comprise sensors to measure the measured current and measured voltage of an ESS. In various embodiments, the measurement unit 310 may measure the current output from stack J. The measurement unit 310 may determine the measured voltage of one or more of the cells of each of the one or more stacks J. The measurement unit 310 may measure the measured current of each of the cells in a stack J. The measurement unit 310 may be in the stack, J, or in proximity to stack, J.

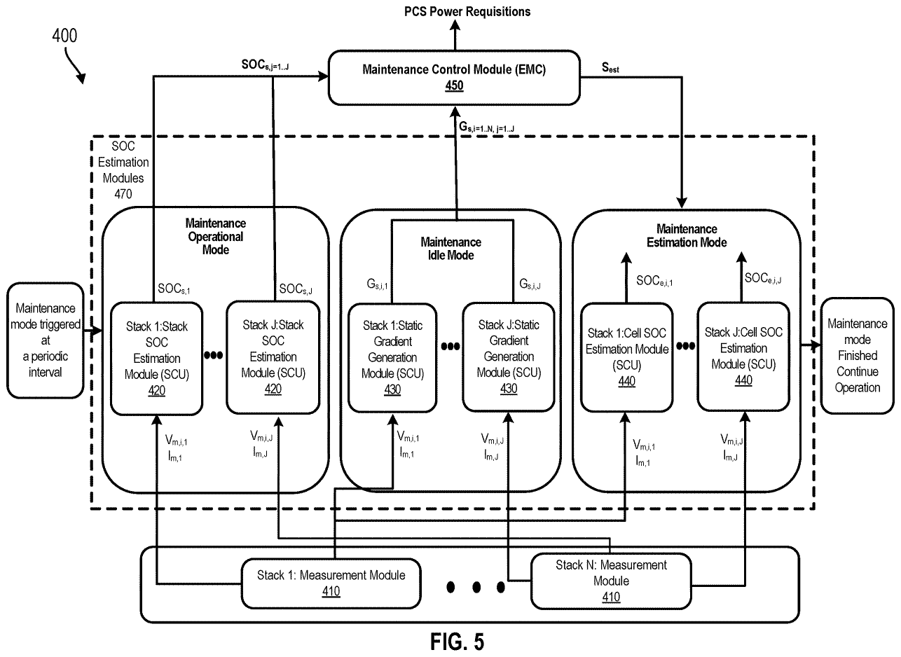

In various embodiments, the state-of-charge estimation system 300 may further comprise a stack computing unit 350 for one or more stacks J. In various embodiments, the stack computing unit 350 may be in connection with the measurement unit 310 and configured to receive the measured voltage of one or more cells of a stack J and/or measured current of a stack J. In various embodiments, stack computing unit 350 is configured to provide measurements, the measurements including the measured cell voltage and measured current of one or more stacks, to the energy management controller 360. The stack computing unit 350 may determine a stack state-of-charge estimate and an open circuit voltage curve (OCV) gradient. The stack computing unit 350 may determine a stack state-of-charge estimate and an open circuit voltage curve (OCV) gradient based on the measured voltage and/or measured current, as described in more detail with reference to FIG. 5. The stack computing unit 350 may provide the stack state-of-charge estimate to the energy management controller 360 during operation. The stack computing unit 350 may provide the OCV gradient to the energy management controller 360 when the ESS is in idle mode. In various embodiments, each of the J stacks may comprise a stack computing unit 350. In various embodiments, the computing unit 350, may estimate the cell state-of-charge when sufficient estimation information is available. The energy management controller 360 is responsible for bringing the battery to specific states in the OCV curve, where such estimation is possible.

The energy management controller 360 may be configured to receive the stack state-of-charge estimates and/or OCV gradient from the stack computing unit 350 and send power requests to the power conversion system 370. The energy management controller 360 may receive the stack state-of-charge estimates and/or OCV gradient from each of the stack computing unit 350 associated with each stack J.

The energy management controller 360 may provide power requests to the power conversion system 370, during normal operation. During maintenance mode, the energy management controller 360 may use the stack SOC estimates for the J stacks and the OCV gradient signals for the J stacks and determine whether to charge or discharge the ESS or rest. For example, the energy management controller 360 may determine whether to charge or discharge the ESS or rest based on the stack SOC estimates and OCV gradients. By charging and discharging the energy storage system, the battery will be brought to specific points in the OCV curve that will allow for more improved cell SOC estimation. The energy management controller 360 may run the maintenance control module software, as described with more detail with reference to FIG. 5.

The state-of-charge estimation system 300 may further comprise a power conversion system 370. The power conversion system 370 may interface between the ESS, such as the multi-stack system, and the external electrical grid or load. The power conversion system 370 may manage the flow of power into or out of the ESS. In an example embodiment, the power conversion system 370 can be a bidirectional inverter. The power conversion system 370 may be configured to take energy from the grid or load or provide energy to the grid or load.

### Maintenance Policy

In various embodiments, the energy storage system can operate in two modes: normal operation or maintenance mode. In normal operation, the ESS functions as intended, storing and delivering energy efficiently to support end applications such as grid stability, load balancing, or backup power. In maintenance mode, the ESS is brought out of operation and a targeted power profile is applied. The purpose of this maintenance cycle is to recalibrate algorithm parameters, correcting errors in SOC estimation, cell balancing, SOH, cell capacity, and cell resistance to ensure optimal performance and accuracy. As discussed in more detail herein, disclosed embodiments may use maintenance cycles (i.e. switching from normal operation to maintenance mode) to determine accurate cell level SOC estimates.

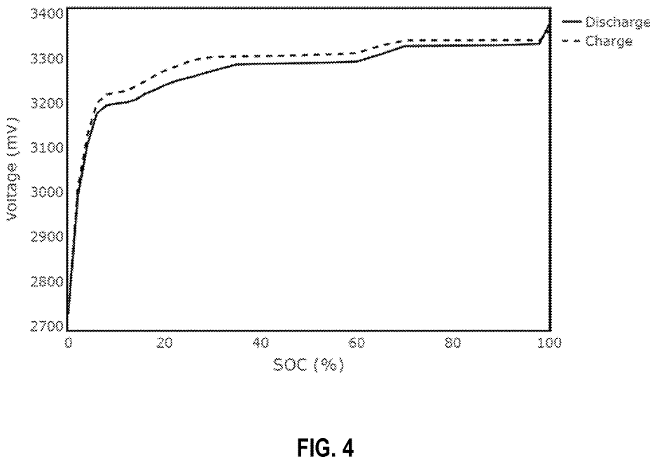

In various embodiments, the state-of-charge estimation system 300 may determine an open circuit voltage (OCV) curve of the ESS. The OCV may be the measured voltage when the ESS is at rest and in equilibrium. The state-of-charge estimation system 300 may use the OCV in determining the cell SOC. With reference to FIG. 4, an example diagram of an OCV curve diagram showing an OCV curve, is shown in accordance with various embodiments. In various embodiments, the OCV curve diagram may comprise the cell state-of-charge compared to the cell voltage. The OCV curve may be determined by an OCV curve module as described in U.S. application Ser. No. 18/677,436 filed May 29, 2024, and incorporated herein as reference.

In various embodiments, OCV curve may be used by the stack state-of-charge estimation module 420, the static gradient generation modules 430 and the cell state-of-charge estimation module 440, as described in more detail with reference to FIG. 5.

With reference now to FIG. 5, a SOC estimation system 400 is shown, in accordance with various embodiments. The SOC estimation system 400, as shown in FIG. 5, depicts the software modules of the SOC estimation system. The software modules of the SOC estimation system 400 are configured to communicate with the hardware modules of SOC estimation system 300, as shown and described with reference to FIG. 3. For example, the hardware of SOC estimation system 300 may send measurements and signals to the SOC estimation system 400 and the SOC estimation system 400 may direct the various components of the SOC estimation system 300, as described in more detail herein.

in various embodiments, a SOC estimation system 400 may comprise a maintenance control module 450, SOC estimation modules 470, and one or more measurement modules 410. In various embodiments, the SOC estimation modules 470 may comprise a stack state-of-charge estimation module 420, a static gradient generation module 430 and/or a cell state-of-charge estimation module 440.

The energy management controller 360 and/or the stack computing unit 350 may implement the SOC estimation modules 470, and/or the maintenance control module 450, as shown and described with reference to FIG. 5. In various embodiments, the energy management controller 360 may implement the SOC estimation modules 470 and/or the maintenance control module 450. In various embodiments, the stack computing unit 350 may implement the SOC estimation modules 470 for each of the one or more stacks.

In an example embodiment, the stack computing unit 350 may be a single computing unit. In an example embodiment, the stack computing unit 350 can be multiple computing units. The stack computing unit 350 may output stack estimates and control information for one or more stacks.

In various embodiments, the SOC estimation system 400 may be in direct or indirect communication with energy management controller 360, as described with reference to FIG. 3. For example, the measurement module 410 of the SOC estimation system 400 may be in communication with the energy management controller 360 to receive the measurements from the measurement unit 310. The measurement module 410 may be configured to measure the current measurement and/or voltage measurement for the stacks J.

With continued reference to FIG. 5, in an example embodiment, the measurement module 410 may be configured to measure the cell voltage for each cell in a stack and the stack current for the full stack. The measurement module 410 may comprise a separate measurement module 410 for each stack J. The measurement module 410 may be similar in design and function to that of measurement unit 310 as described with reference to FIG. 3. The measurement module 410 may comprise the software module configured to receive information from the hardware of the measurement unit 310. The measurement module 410 may comprise the measurement unit 310. In various embodiments, the measurement module 410 may comprise a current measurement circuit and a voltage measurement circuit. In various embodiments, the measurement unit 310 may measure the voltage of each of the cells in a stack, also referred to herein as the cell voltage measurement or cell measured voltage. In various embodiments, the measurement unit 310 may measure the current of a stack, also referred to as the stack current.

In various embodiments, the measurement module 410 may measure the measured current, wherein the measured current is the current of a stack of cells. In various embodiments, the measurement module 410 may comprise a current measurement module. In various embodiments, the current measurement module may comprise a current sensor, such as a hall effect sensor, a current shunt, or the like. In various embodiments, the current measurement module may comprise a current sensor located convenient to measuring the current into or out of a stack in an ESS. In various embodiments, the current measurement module may be connected to each stack. In various embodiments, the cells in each of the one or more stacks may be connected in series, therefore a measurement of the current into or out of the stack is equivalent to the current into or out of each cell. In an example embodiment, a stack may have only one cell. In various embodiments, the current measurement module is configured to sample current at a time step k. For example, the current measurement module may sample the current of each of the one or more stacks in 1 second intervals, though any sampling period can be used. In an example embodiment, the current measurement module can be any suitable current measurement device that is configured to measure a current (into or out of the stack) and to generate a measured current, I_{m,j}, representing a measured current for each of the stacks.

In various embodiments, the measurement module 410 may measure the measured voltage, wherein the measured voltage may be the voltage of the cells in a stack of cells. In various embodiments, the measurement module 410 may comprise a voltage measurement circuit. In various embodiments, the measurement module 410 may comprise a voltage measurement module, which may comprise a voltage sensor, such as a capacitive voltage sensor, a resistive type voltage sensor, or the like. In various embodiments, the measurement module 410 may comprise a voltage sensor which may be located convenient to measuring the voltage across each cell in a stack of cells of an ESS. In various embodiments, the voltage measurement module of the measurement module 410 can be any suitable voltage measurement device that is configured to measure a voltage and to generate a measured voltage, V_{m,i,j}, representing the measured voltage across each cell in a stack. In various embodiments, the measurement module 410 may sample voltage measurements at a time step, k. In various embodiments, the measurement module 410 may sample voltage measurements where k is 1 second, though any suitable time step can be used. In various embodiments, the measurement module 410 may determine or measure a cell voltage, wherein the cell voltage is the measured voltage of one or more cells connected in series in a stack. In various embodiments, measurement module 410 may determine or measure a plurality of cell voltages across a plurality of stacks, wherein the plurality of cell voltages is the measured voltage of each of the one or more cells of one or more stacks.

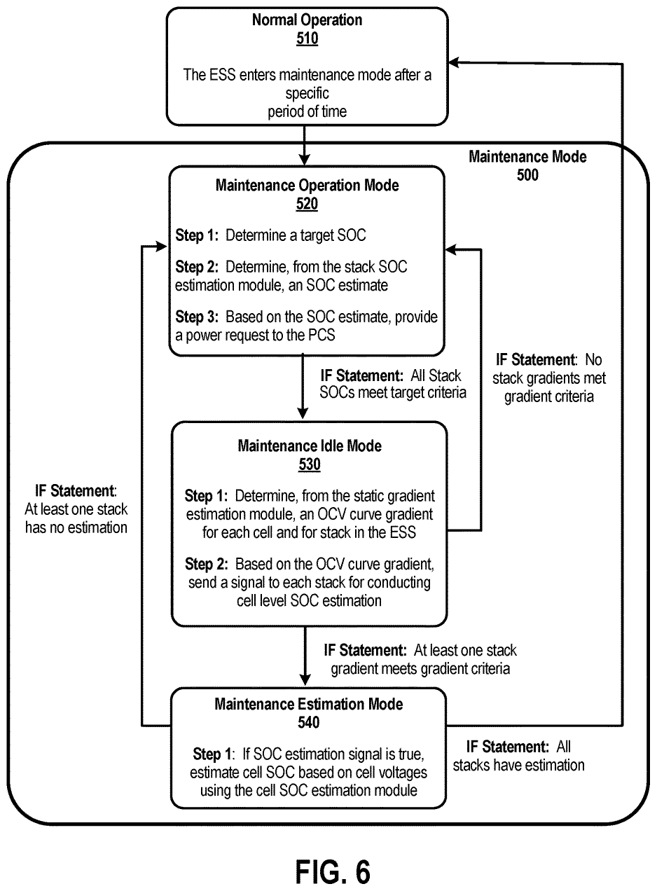

In various embodiments, SOC estimation modules 470 may comprise a stack SOC estimation module 420, a static gradient generation module 430, and a cell SOC estimation module 440. Each of the SOC estimation modules 470 may be configured to receive the measured voltage and the measured current from the measurement modules. The calculations within the SOC estimation modules 470 may be configured to operate only when the ESS is in maintenance mode, as described in greater detail with reference to FIG. 6. Additionally, the SOC estimation modules 470 may operate when the ESS is in one of three maintenance modes: maintenance operation mode, maintenance idle mode, or maintenance estimation mode. In maintenance operation mode, the current may flow through the battery, and the battery is being brought to a specific point in the OCV curve by sending signals to the power conversion system as detailed in FIG. 3. In maintenance idle mode, the battery is at rest at a specific point in the OCV curve. In maintenance estimation mode, a sufficient period of time has elapsed and the conditions for cell SOC estimation is met. For example, the stack SOC estimation module 420 may operate when the ESS is in maintenance operation mode, the static gradient generation module 430 may operate when the ESS is in maintenance idle mode, and a cell SOC estimation module 440 may operate when the ESS is in maintenance estimation mode. The maintenance control module 450 may assist in determining the maintenance mode the ESS is operating in and which of the SOC estimation modules 470 to implement. Additional logic regarding determination of the three modes the system is described in detail with reference to FIG. 6.

The stack SOC estimation module 420 may be implemented on the stack computing unit 350. In some embodiments, the stack SOC estimation module 420 may be implemented on energy management controller 360. In various embodiments, the SOC estimation system 400 may comprise J number of stack SOC estimation module 420, for each stack J in the ESS. The stack SOC estimation module 420 for the Jth stack may receive the cell voltage measurements V_{m,i,j} and stack current I_{m,j}. For example, the stack SOC estimation module 420 of stack 1, it will take measurement V_{mi,1} and stack current I_{m,1}. The stack SOC estimation module 420 module for the Jth stack may determine the stack SOC estimate denoted SOC_{s,j}. The SOC_{s,j} may be a stack SOC. The stack SOC may be used during operation of the ESS in maintenance mode and used to determine whether the ESS should be brought to IDLE mode. The stack SOC estimation module 420 may output the stack SOC to the maintenance control module 450.

The stack SOC estimation module 420 may estimate the stack SOC, SOC_{s,j} of each of the one or more stacks based on accumulating the current over time as shown in the following equation:

$${SOC}_{s , j , k} = {SOC}_{s , j , k - 1} - \frac{( {I}_{m , j , k} ) Δ t}{{Cap}_{nom , j}}$$

Where Cap_{nom,j} is the capacity of the stack, and Δt is an accumulation time step: The current at time step k, and the SOC estimate from the previous time step, k−1, is used to determine the SOC, denoted SOC_{s,j,k}, at time step k. In various embodiments, the stack SOC estimation module 420 may estimate the stack SOC, SOC_{s,j}, of one or more stacks, J, based on a recursive Bayesian filter. The stack SOC estimation module 420, may estimate the stack SOC by taking the derivative of the measured cell voltage and correlating gradient in the cell voltage with the gradient in the OCV curve. The stack SOC estimation module 420 may estimate the stack SOC using any suitable type of estimation algorithm for estimating stack level SOC.

In various embodiments, the static gradient generation module 430 may operate when the ESS is in the maintenance idle mode. An idle state is when the ESS is at rest. For example, an idle state is when the energy management controller 360 sends a power request of zero to the power conversion system 370, as shown in FIG. 3 and the measured current is zero. In various embodiments, the SOC estimation system 400 comprises J static gradient generation modules 430, one for each stack, J, in the ESS. The static gradient generation modules 430 may receive the cell voltage measurement V_{m,i,j} and stack current I_{m,j}. For example, the static gradient generation modules 430 of stack 1, will receive cell voltage measurement V_{m,i,1} and stack current measurement I_{m,1}.

In various embodiments, the static gradient generation module 430 may operate when the ESS is at rest for a configurable period of time, i.e. rest period. For example, the rest period, in various embodiments, may be more than 1 hour prior to the static gradient generation module 430 estimating the OCV curve gradient.

In various embodiments, the static gradient generation module 430 may determine the gradient of the open circuit voltage curve, also referred to as the “open circuit voltage curve gradient” or simply “gradient”. In various embodiments, the static gradient generation module 430 may determine the gradient for the jth stack and the ith cell based on the following procedure. (Note that for conciseness, the index j is not shown so the equations below can be thought of as applying to a stack j). The measurement error can be defined as ϵₘₑₐₛ~N(0, σₑᵣᵣ²), where the value of σₑᵣᵣ can be determined experimentally. Based on the measurement error standard deviation, σₑᵣᵣ and by incorporating hysteresis, the upper limits and lower limits for the open circuit voltage are calculated based on:

V_{ocv,up,i}=V_{m,i}−(V_{hys,i}+α σₑᵣᵣ); and V_{ocv,low,i}=V_{m,i}+(V_{hys,i}+α σₑᵣᵣ). V_{hys,i} represents the hysteresis of the ith cell, used to describe the effect of current direction on the open-circuit voltage of the ESS. The value of a is the confidence interval, which may be adjusted based on the desired confidence in output. For example, the confidence interval may be a 95% or 99% confidence interval. For an ESS with hysteresis, discharge from full to 50% SO C will produce a different OCV value than charge from empty to 50% SOC. The voltage hysteresis value, V_{hys,k}, may be calculated based on the equation:

$${V}_{hys , i , k} = exp ( \frac{{ηI}_{L , k} γ}{{c}_{n}} ) {V}_{hys , i , k - 1} + ( 1 - exp ( \frac{{ηI}_{L , k} γ}{{c}_{n}} ) ) M ( SOC , S \dot{O} C )$$

Where M(SOC,S\dot{O}C) is the maximum polarization due to hysteresis, sgn(S\dot{O}C) is used to differentiate between charging and discharging and γ is the decay of the hysteresis voltage.

The value of M(SOC,S\dot{O}C) can be determined offline using the OCV curve. The SOC may be calculated based on the inverse of the OCV curve:

$${SOC}_{up , i} = {f}_{soc} ( {V}_{ocv , up , i} ) and {SOC}_{low , i} = {f}_{soc} ( {V}_{ocv , low , i} )$$

Where, fₛₒₑ represents the inverse of the OCV curve. The gradient at both the upper and lower SOC points may be calculated based on:

$${G}_{s , i} = \frac{{f}_{ocv} ( {SOC}_{up , i} + δ ) - {f}_{ocv} ( {SOC}_{up , i} - δ )}{2 δ}$$

Where δ is a small perturbation of SOC and f_{ocv} represents the OCV curve. For example, δ can be 1% SOC. The static gradient generation module 430 for the jth stack may output an output signal G_{s,j,i} which is a gradient signal used to determine by the maintenance control module 450 whether the ESS should be returned to maintenance operation mode or move on to maintenance estimation mode.

In various embodiments, the maintenance control module 450 may determine an estimation signal S_{est,j}, based on the stack SOC for one or more stacks and the OCV curve gradient for one or more stacks. In various embodiments, the estimation signal may be provided to the cell SOC estimation module 440.

In various embodiments, the cell SOC estimation module 440 is configured to determine the cell SOC estimates, as described in more detail with reference to FIG. 5.

In various embodiments, the maintenance control module 450 may change the state of the ESS, as described in greater detail with reference to FIG. 5. The maintenance control module 450 may change the state of the ESS based on specific conditions. The maintenance control module 450 may calculate a specific condition or output based on the mode or state of the ESS.

With reference to FIG. 6 and continued reference to FIG. 5, the maintenance control module 450 may operate in one or more modes or states, including normal operation 510, and maintenance mode 500. Maintenance mode 500 may comprise maintenance operation mode 520, maintenance idle mode 530, and/or maintenance estimation mode 540.

In various embodiments, in normal operation 510, the SOC estimation modules 470 may be inactive. The ESS may enter maintenance mode 500 after a specific time interval or other suitable condition is met. For example, the ESS may enter maintenance mode 500 every 2 weeks or once a month. The ESS may enter maintenance mode 500 after a specific amount of charge has flowed through the battery.

The ESS may transition to operation mode 520 periodically to determine the cell SOC and/or reset the cell level SOC. In various embodiments, the ESS may enter maintenance operation mode 520 and use the stack SOC estimation module 420 to determine whether to remain in maintenance operation mode or switch to maintenance idle mode. For example, the maintenance operation mode 520 may comprise one or more step performed by the maintenance control module 450 and stack SOC estimation module 420, including: Step 1: the maintenance control module 450 may determine a target SOC, based on the region of the gradient of the OCV curve (i.e. the SOC where the gradient starts, and the SOC where the gradient ends).

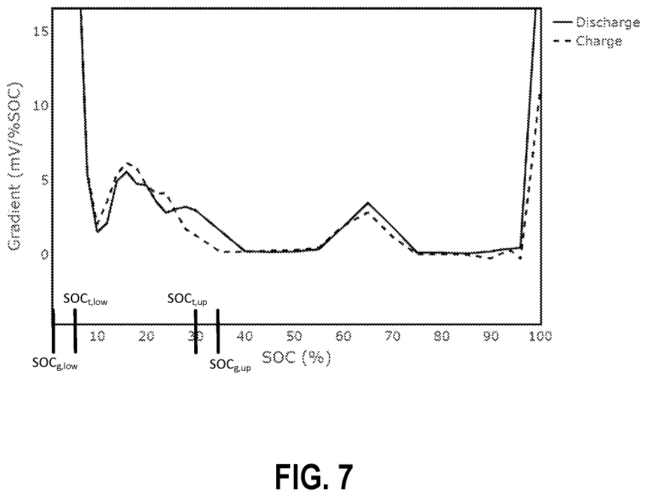

With reference to FIG. 7, an example gradient of the OCV curve as a function of SOC is shown, in accordance with various embodiments. For example, for LFP, the bottom level gradient starts at approximately SOC 35% and ends at SOC 0%. This can be expressed as SOC_{g,up} where the SOC the gradient starts and SOC_{g,low}, where the SOC the gradient ends. The maintenance control module 450 may determine the SOC error, SOCₑᵣᵣ, based on experimentation. The maintenance control module 450 may calculate the target SOC, denoted SOC_{t,up} or SOC_{t,low} based on the equation:

$${SOC}_{t , up} = {SOC}_{g , up} - {SOC}_{err , j} ; and {SOC}_{t , low} = {SOC}_{g , low} + {SOC}_{err , j} .$$

Step 2: The maintenance control module 450 may receive the inputs of stack SOC estimation SOC_{s,j} from the stack SOC estimation module 420. Step 3: The maintenance control module 450 may provide a power request to the PCS using the stack SOC estimates, based on the following logic: When SOC_{s,j}>SOC_{t,up}, request a constant power discharge. If Statement: SOC_{s,1} . . . SOC_{s,J}<SOC_{t,up} for ALL stacks: Request a power of zero and go to maintenance idle mode 530. Else: Continue discharge (remain in maintenance operation mode 520). When SOC_{s,j}<SOC_{t,low}, request a constant power charge. If Statement: SOC_{s,1} . . . SOC_{s,J}>SOC_{t,low} for ALL stacks: Request a power of zero and go to maintenance idle mode 530. Else: Continue charge (remain in maintenance operation mode 520).

In various embodiments, the maintenance idle mode 530 may comprise one or more steps including: Step 1: the maintenance control module 450 receives inputs of the estimated OCV gradient for each cell and for each stack G_{s,i,j} from the static gradient generation module 430. Step 2: the maintenance control module 450 sends an estimation signal for each stack to the cell SOC estimation module based on the OCV curve gradients. If Statement: G_{s,i,1} . . . G_{s,i,J}>=G_{conf} for at least one stack, then the maintenance control module 450 sends an estimation signal S_{est,j} for each stack. The estimation signal indicates that there is sufficient gradient or information for estimating the cell level SOC and the SOC estimation modules 470 goes into maintenance estimation mode 540. If Statement: G_{s,i,1} . . . G_{s,i,J}<G_{conf} for all stacks: transition back to operation mode 520 and update the target SOC by a configurable amount. For example, if the target SOC was 30%, the next target might be 25%. Or if the target SOC was 65%, the next target might be 68%.

In various embodiments, when the SOC estimation modules 470 enters maintenance estimation mode 540 the maintenance control module 450 may send an SOC estimation signal set to “true” to the cell SOC estimation module 440. The cell SOC estimation module 440 may estimate cell SOC based on cell voltages in response to the estimation signal. The ESS continues to remain in maintenance idle mode 530. If the SOC estimation system 300 fails to estimate cell SOC of one or more stacks, the ESS goes back to maintenance operation mode 520. If the SOC estimation system 300 estimates SOC on all cell and for all the stacks, the system will go back to normal operation 510.

With reference back to FIG. 3 and continued reference to FIG. 5, the SOC estimation system 400 may estimate the cell SOC for the stack J, when the Boolean value of the signal S_{est,j}, is True. The SOC estimation system 400 may estimate the cell SOC for the stack J when there is sufficient information for estimating SOC. The cell SOC for each cell in a stack may be calculated using the following equation:

$${SOC}_{i , k} = {{f}_{soc} ( {V}_{m , i , k} - {V}_{hys , i , k} )}^{- 1} and {V}_{hys , i , k} = exp ( \frac{{ηI}_{L , k} γ}{{c}_{n}} ) {V}_{hys , i , k - 1} + ( 1 - exp ( \frac{{ηI}_{L , k} γ}{{c}_{n}} ) ) < ( SOC , S \dot{O} C ) .$$

Where M(SOC,S\dot{O}C) is the maximum polarization due to hysteresis, sgn(S\dot{O}C) is used to differentiate between charging and discharging and γ is the decay of the hysteresis voltage. The value of M(SOC,S\dot{O}C) can be determined offline using the OCV curve.

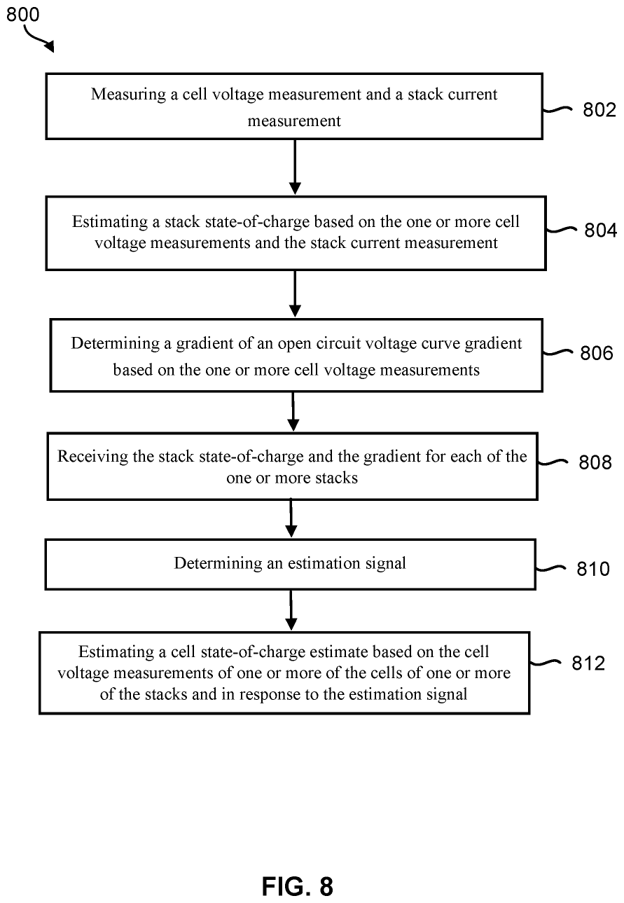

With reference to FIG. 8, a cell state-of-charge estimation method 800 is disclosed herein. In various embodiments, the cell state-of-charge estimation method 800 may comprise measuring a cell voltage measurement and a stack current measurement (step 802). The method may comprise estimating a stack state-of-charge based on the one or more cell voltage measurements and the stack current measurement (step 804). The method may comprise determining a gradient of an open circuit voltage curve based on the one or more cell voltage measurements (step 806). The method may comprise receiving the stack state-of-charge and the gradient for each of the one or more stacks (step 808). The method may comprise determining an estimation signal (step 810). The method may comprise estimating a cell state-of-charge estimate based on the cell voltage measurements of one or more of the cells of one or more of the stacks and in response to the estimation signal (step 812).

In various embodiments, the modules discussed herein can be implemented as and may include one or more processors and/or one or more tangible, non-transitory memories (e.g., memory) and be capable of implementing logic. Each processor can be a general-purpose processor, a digital signal processor (“DSP”), an application specific integrated circuit (“ASIC”), a field programmable gate array (“FPGA”), or other programmable logic device, discrete gate or transistor logic, discrete hardware components, or any combination thereof. The controller can comprise a processor configured to implement various logical operations in response to execution of instructions, for example, instructions stored on a non-transitory, tangible, computer-readable medium configured to communicate with the modules discussed.

System program instructions and/or controller instructions can be loaded onto a non-transitory, tangible computer-readable medium of the modules having instructions stored thereon that, in response to execution by a processor of the modules, cause the modules to perform various operations. The term “non-transitory” is to be understood to remove only propagating transitory signals per se from the claim scope and does not relinquish rights to all standard computer-readable media that are not only propagating transitory signals per se. Stated another way, the meaning of the term “non-transitory computer-readable medium” and “non-transitory computer-readable storage medium” should be construed to exclude only those types of transitory computer-readable media which were found in In Re Nuijten to fall outside the scope of patentable subject matter under 35 U.S.C. § 101.

Benefits, other advantages, and solutions to problems have been described herein regarding specific embodiments. Furthermore, the connecting lines shown in the various figures contained herein are intended to represent exemplary functional relationships and/or physical couplings between the various elements. It should be noted that many alternative or additional functional relationships or physical connections may be present in a practical system. However, the benefits, advantages, solutions to problems, and any elements that may cause any benefit, advantage, or solution to occur or become more pronounced are not to be construed as critical, required, or essential features or elements of the disclosure. The scope of the disclosure is accordingly limited by nothing other than the appended claims, in which reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B, and C may be present in a single embodiment; for example, A and B, A and C, B and C, or A and B and C. Different cross-hatching is used throughout the figures to denote different parts but not necessarily to denote the same or different materials.

Systems, methods, and apparatus are provided herein. In the detailed description herein, references to “one embodiment,” “an embodiment,” “various embodiments,” etc. indicate that the embodiment described may include a particular feature, structure, or characteristic, but every embodiment may not necessarily include the feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether explicitly described. After reading the description, it will be apparent to one skilled in the relevant art(s) how to implement the disclosure in alternative embodiments.

Furthermore, no element, component, or method step in the present disclosure is intended to be dedicated to the public regardless of whether the element, component, or method step is explicitly recited in the claims. No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

It should be understood, however, that the detailed description and specific examples, while indicating exemplary embodiments of the present disclosure, are given for purposes of illustration only and not of limitation. Many changes and modifications within the scope of the instant disclosure may be made without departing from the spirit thereof, and the disclosure includes all such modifications. The corresponding structures, materials, acts, and equivalents of all elements in the claims below are intended to include any structure, material, or acts for performing the functions in combination with other claimed elements as specifically claimed. The scope of the disclosure should be determined by the appended claims and their legal equivalents, rather than by the examples given above. For example, the operations recited in any method claims may be executed in any order and are not limited to the order presented in the claims. Moreover, no element is essential to the practice of the disclosure unless specifically described herein as “critical” or “essential.”

What is claimed:

1. A state-of-charge estimation system, comprising:
an energy storage system comprising one or more stacks, wherein each of the one or more stacks contain one or more cells;
a measurement module comprising a voltage measurement device and a current measurement device;
wherein the voltage measurement device is configured to measure a cell voltage measurement of one or more of the cells of one or more of the stacks;
wherein the current measurement device is configured to measure a stack current measurement of one or more of the stacks;
a stack state-of-charge estimation module for receiving the cell voltage measurements and the stack current measurement and configured to estimate a stack state-of-charge based on the one or more cell voltage measurements and the stack current measurement;
a static gradient generation module for estimating a gradient of an open circuit voltage curve based on the one or more cell voltage measurements;
a maintenance control module configured to determine an estimation signal based on the stack state-of-charge and the gradient for each of the one or more stacks;
wherein the maintenance control module is configured to send instructions to a power conversion system to bring the one or more stacks to a specified state-of-charge based on the stack state-of-charge; and
a cell state-of-charge estimation module configured to estimate a cell state-of-charge estimate based on the cell voltage measurements of one or more of the cells of one or more of the stacks and in response to the estimation signal.

2. The system of claim 1, wherein the maintenance control module is configured to control the energy storage system to be in an idle state for a period of time, and wherein the cell state-of-charge estimation module determines the cell state-of-charge estimate when the energy storage system is in the idle state.

3. The system of claim 1, wherein the stack state-of-charge estimation module is configured to estimate the stack state-of-charge based on the stack current measurements over a period of time.

4. The system of claim 1, wherein the maintenance control module provides the estimation signal to the cell state-of-charge estimation module and the cell state-of-charge estimation module is configured to estimate the cell state-of-charge estimate for each of the cells of one or more of the stacks in the energy storage system based on the estimation signal.

5. The system of claim 1, wherein the static gradient generation module is configured to estimate the gradient when the energy storage system is in an idle state and accounting for battery hysteresis of the energy storage system.

6. The system of claim 1, wherein the maintenance control module is configured to send instructions to the power conversion system to rest at the specified state-of-charge; and
wherein the maintenance control module determines the estimation signal based on the gradient of the open circuit voltage curve at this point.

7. A cell state-of-charge estimation method, comprising:
measuring, by a measurement module comprising a voltage measurement device and a current measurement device, a cell voltage measurement of one or more cells of one or more stacks of an energy storage system, and a stack current measurement of one or more of the stacks;
estimating, by a stack state-of-charge estimation module, a stack state-of-charge based on one or more cell voltage measurements and the stack current measurement;
determining, by a static gradient generation module, a gradient of an open circuit voltage curve based on the one or more cell voltage measurements;
determining, by a maintenance control module, an estimation signal based on the stack state-of-charge and the gradient for each of the one or more stacks;
wherein the maintenance control module is configured to send instructions to a power conversion system to bring the one or more stacks to a specified state-of-charge based on the stack state-of-charge; and
estimating, by a cell state-of-charge estimation module, a cell state-of-charge estimate based on the cell voltage measurements of one or more of the cells of the one or more stacks and in response to the estimation signal.

8. The method of claim 7, wherein the maintenance control module is configured to control the energy storage system to be in an idle state for a period of time, and wherein the cell state-of-charge estimation module determines the cell state-of-charge estimate when the energy storage system is in the idle state.

9. The method of claim 7, wherein the stack state-of-charge estimation module is configured to estimate the stack state-of-charge based on the stack current measurements over a period of time.

10. The method of claim 7, wherein the maintenance control module provides the estimation signal to the cell state-of-charge estimation module and the cell state-of-charge estimation module is configured to estimate the cell state-of-charge estimate for each of the cells of one or more of the stacks in the energy storage system based on the estimation signal.

11. The method of claim 7, wherein the static gradient generation module is configured to estimate the gradient when the energy storage system is in an idle state and accounting for battery hysteresis of the energy storage system.

12. The method of claim 7, wherein the cell state-of-charge estimation module is configured to estimate the cell state-of-charge estimate when the energy storage system is in a maintenance estimation mode.

13. The method of claim 7, wherein the maintenance control module is configured to send instructions to the power conversion system to rest at the specified state-of-charge; and
wherein the maintenance control module determines the estimation signal based on the gradient of the open circuit voltage curve at this point.

14. A state-of-charge estimation device comprising:
an energy storage system comprising one or more stacks, wherein each of the one or more stacks contain one or more cells;
a measurement module comprising a voltage measurement device and a current measurement device; wherein the voltage measurement device is configured to measure a cell voltage measurement of one or more of the cells of one or more of the stacks; wherein the current measurement device is configured to measure a stack current measurement of one or more of the stacks;
a stack computing unit for each of the one or more stacks, the stack computing unit for receiving the cell voltage measurement and the stack current measurement and determining a stack state-of-charge;
an energy management controller for determining a power request based on the stack state-of-charge; and
a power conversion system for controlling the energy storage system based on the power request.

15. The device of claim 14, wherein the energy management controller further comprises:
a maintenance control module configured to determine an estimation signal based on the stack state-of-charge and a gradient for each of the one or more stacks; and
wherein the maintenance control module is configured to send instructions to the power conversion system to bring the one or more stacks to a specified state-of-charge based on the stack state-of-charge.

16. The device of claim 14, wherein the stack computing unit further comprises:
a stack state-of-charge estimation module for receiving the cell voltage measurements and the stack current measurement and configured to estimate the stack state-of-charge based on the one or more cell voltage measurements and the stack current measurement.

17. The device of claim 14, wherein the stack computing unit further comprises:
a static gradient generation module for estimating a gradient of an open circuit voltage curve based on the one or more cell voltage measurements.

18. The device of claim 14, wherein the stack computing unit further comprises:
a cell state-of-charge estimation module configured to estimate a cell state-of-charge estimate based on the cell voltage measurements of one or more of the cells of one or more of the stacks and in response to an estimation signal.

19. The device of claim 14, wherein a static gradient generation module is configured to estimate a gradient of an open circuit voltage curve accounting for a battery hysteresis of the energy storage system; and wherein the static gradient generation module is configured to estimate the gradient when the energy storage system is in an idle state.

20. The device of claim 14, further comprising a maintenance control module,
wherein the maintenance control module is configured to send instructions to the power conversion system to rest at a specified state-of-charge; and
wherein the maintenance control module determines an estimation signal based on a gradient of an open circuit voltage curve at this point.
